(19) United States
(12) Patent Application Publication
(10) Pub. No.: US 2014/0167006 A1
(43) Pub. Date: Jun. 19, 2014

(54) FLEXIBLE SUBSTRATE FOR ROLL-TO-ROLL PROCESSING AND METHOD OF MANUFACTURING THE SAME

(71) Applicant: Samsung Display Co., Ltd., Yongin-City (KR)

(72) Inventor: Kihyun Kim, Yongin-City (KR)

(21) Appl. No.: 14/035,613

(22) Filed: Sep. 24, 2013

(30) Foreign Application Priority Data
Dec. 14, 2012 (KR) 10-2012-0146633

(51) Int. Cl. H01L 27/32; B05D 1/28; C23C 14/34; B29C 59/04; C23C 16/22

(52) U.S. Cl. CPC H01L 27/3244; B29C 59/04; C23C 16/22; C23C 14/34; B05D 1/28
USPC 257/40; 428/161; 264/293; 427/248.1; 427/275

(57) ABSTRACT

In a flexible substrate for roll-to-roll processing having improved thermal, mechanical, and chemical stabilities, a method of manufacturing the same, and an organic light emitting display apparatus including the same, the flexible substrate for roll-to-roll processing includes a base film formed of an organic material and an inorganic mesh pattern formed of inorganic material. The base film includes a first surface and a second surface opposite to the first surface, the first surface comprising first trenches extending in a first direction and second trenches extending in a second direction. The inorganic mesh pattern buries the first trenches and the second trenches.

### CLAIM OF PRIORITY

This application makes reference to, incorporates into this specification the entire contents of, and claims all benefits accruing under 35 U.S.C. §119 from an application earlier filed in the Korean Intellectual Property Office filed on Dec. 14, 2012 and there duly assigned Serial No. 10-2012-0146633.

### BACKGROUND OF THE INVENTION

1. Field of the Invention

The present invention relates to a flexible substrate for roll-to-roll processing, and more particularly to a flexible substrate for roll-to-roll processing having improved thermal, mechanical, and chemical stabilities, and a method of manufacturing the same.

2. Description of the Related Art

Plastic substrates are currently used for roll-to-roll processing. Plastic substrates used for roll-to-roll processing are generally manufactured in a film type by using polymer materials. Plastic substrates manufactured by using the polymer material have extraordinary flexibility, whereas they have problematically low thermal, mechanical, and chemical stabilities due to a unique property of the polymer material.

In a case where such plastic substrates are used to perform roll-to-roll processing, if a processing temperature is high or a processing frequency increases, plastic substrates are modified like an increase in lengths thereof or wrinkles. Due to such low stabilities of plastic substrates, roll-to-roll processing may be used only in products that may be manufactured by a simple processing, and may not be used in flexible displays requiring complicated and difficult processing.

### SUMMARY OF THE INVENTION

The present invention provides a flexible substrate for roll-to-roll processing having improved thermal, mechanical, and chemical stabilities.

The present invention also provides a method of manufacturing the flexible substrate for roll-to-roll processing.

The present invention also provides an organic light emitting display apparatus comprising the flexible substrate for roll-to-roll processing.

According to an aspect of the present invention, there is provided a flexible substrate for roll-to-roll processing including: a base film comprising a first surface and a second surface opposite to the first surface, the first surface comprising first trenches extending in a first direction and second trenches extending in a second direction, and formed of an organic material; and an inorganic mesh pattern filled in the first trenches and the second trenches and formed of an inorganic material.

The first trenches and the second trenches may cross each other and are arranged in a mesh shape.

The base film may include at least one selected from the group consisting of polyimide (PI), polyethylene terephthalate (PET), polyethylene naphthalate (PEN), polycarbonate (PC), polyarylate (PAR), polyetherimide (PEI), and polyethersulfone (PES).

The inorganic mesh pattern may include an inorganic insulation material.

The inorganic mesh pattern may include metal.

The flexible substrate may further include an inorganic insulation layer stacked on the first surface of the base film. The inorganic insulation layer may include a first inorganic insulation layer and a second inorganic insulation layer stacked on the first inorganic insulation layer.

The flexible substrate may further include an inorganic insulation layer stacked on the second surface of the base film, wherein an element is formed on the inorganic insulation layer.

The flexible substrate may have a scroll shape in a third direction that is different from the first direction and second direction.

According to another aspect of the present invention, there is provided a method of manufacturing a flexible substrate for roll-to-roll processing, comprising: preparing a base film including a first surface and a second surface opposite to the first surface, and formed of an organic material; forming first trenches extending in a first direction and second trenches extending in a second direction in the first surface of the base film; and forming an inorganic mesh pattern by filling an inorganic material in the first trenches and the second trenches.

The first trenches and the second trenches may be formed by using a thermal type roll imprinting method.

The inorganic mesh pattern may be formed by filling the inorganic material in the first trenches and the second trenches by using a doctor blade and removing the inorganic material remaining on the first surface of the base film.

The method may further include stacking an inorganic insulation layer on at least one of the first surface and the second surface of the base film.

The inorganic insulation layer may be stacked by using a sputtering method or a chemical vapor deposition method.

According to another aspect of the present invention, there is provided an organic light emitting display apparatus comprising:

a flexible substrate:

a display unit comprising thin film transistors disposed on the flexible substrate and organic light emitting elements connected to the thin film transistors; and

an encapsulation thin film formed on the flexible substrate so as to cover the display unit, and having a structure in which a plurality of inorganic films and a plurality of organic films are alternately stacked;

wherein the flexible substrate comprises:

a base film including a first surface and a second surface opposite to the first surface, the first surface comprising first trenches extending in a first direction and second trenches extending in a second direction, and formed of an organic material; and

an inorganic mesh pattern filled in the first trenches and the second trenches, and formed of an inorganic material.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a schematic perspective view of a flexible substrate for roll-to-roll processing according to an embodiment of the present invention;

FIG. 2 is a schematic plan view of the flexible substrate for roll-to-roll processing of FIG. 1;

FIG. 3 is a schematic cross-sectional view of the flexible substrate for roll-to-roll processing of FIG. 1;

FIG. 4 is a schematic cross-sectional view of a flexible substrate for roll-to-roll processing according to another embodiment of the present invention;

FIG. 5 is a schematic cross-sectional view of a flexible substrate for roll-to-roll processing according to another embodiment of the present invention;

FIG. 6 is a schematic cross-sectional view of a flexible substrate for roll-to-roll processing according to another embodiment of the present invention;

FIG. 7 is a schematic cross-sectional view of a flexible substrate for roll-to-roll processing according to another embodiment of the present invention;

FIG. 8 is a schematic cross-sectional view of a flexible substrate for roll-to-roll processing according to another embodiment of the present invention;

FIG. 9 is a schematic cross-sectional view of a flexible substrate for roll-to-roll processing according to another embodiment of the present invention;

FIG. 10 is a schematic cross-sectional view of a flexible substrate for roll-to-roll processing according to another embodiment of the present invention;

FIGS. 11A through 11D are schematic cross-sectional views for explaining a method of manufacturing a flexible substrate for roll-to-roll processing according to an embodiment of the present invention;

FIG. 12 is a schematic cross-sectional view of an organic light emitting display apparatus including a flexible substrate for roll-to-roll processing according to another embodiment of the present invention; and

FIG. 13 is a detailed cross-sectional view of a part of the organic light emitting display apparatus of FIG. 12.

### DETAILED DESCRIPTION OF THE INVENTION

Hereinafter, the inventive concept will be described more fully with reference to the accompanying drawings, in which exemplary embodiments of the inventive concept are shown. These embodiments are provided so that this disclosure will be thorough and complete, and will fully convey the scope of the inventive concept to those of ordinary skill in the art. As the inventive concept allows for various changes and numerous embodiments, particular embodiments will be illustrated in the drawings and described in detail in the written description. However, this is not intended to limit the inventive concept to particular modes of practice, and it is to be appreciated that all changes, equivalents, and substitutes that do not depart from the spirit and technical scope of the inventive concept are encompassed in the inventive concept.

In the drawings, like reference numerals denote like elements and the sizes or thicknesses of elements may be exaggerated for clarity of explanation.

The terms used in the present specification are merely used to describe particular embodiments, and are not intended to limit the inventive concept. An expression used in the singular encompasses the expression in the plural, unless it has a clearly different meaning in the context. In the present specification, it is to be understood that the terms such as “including” or “having,” etc. are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added. As used herein, the term “and/or” includes any and all combinations of one or more of the associated listed items. While such terms as “first,” “second,” etc. may be used to describe various components, such components must not be limited to the above terms. The above terms are used only to distinguish one component from another. In the description below, when it is disclosed that a first feature is connected to, combined with, or linked to a second feature, this does not exclude that a third feature may be interposed between the first feature and the second feature. Also, when a first element is disposed on a second element, this does not exclude that a third element is interposed between the first element and the second element. However, when the first element is directly disposed on the second element, this excludes that the third element is interposed between the first element and the second element.

Unless defined differently, all terms used in the description, including technical and scientific terms, have the same meaning as generally understood by one of ordinary skill in the art to which this invention pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Expressions such as “at least one of,” when preceding a list of elements, modify the entire list of elements and do not modify the individual elements of the list.

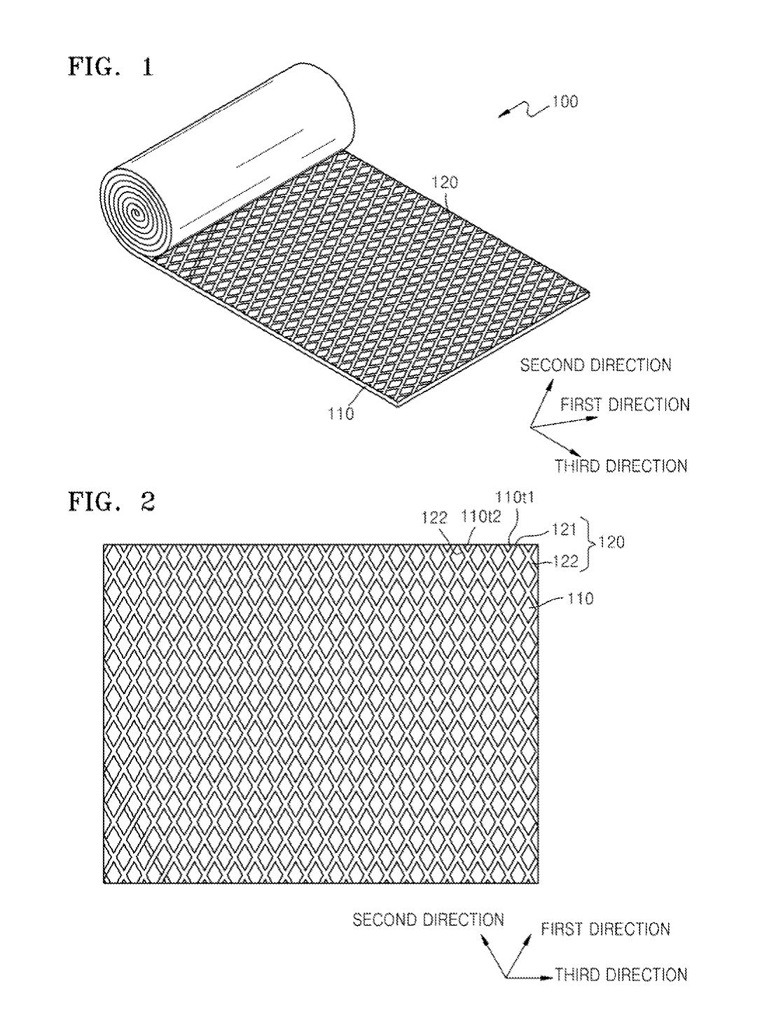

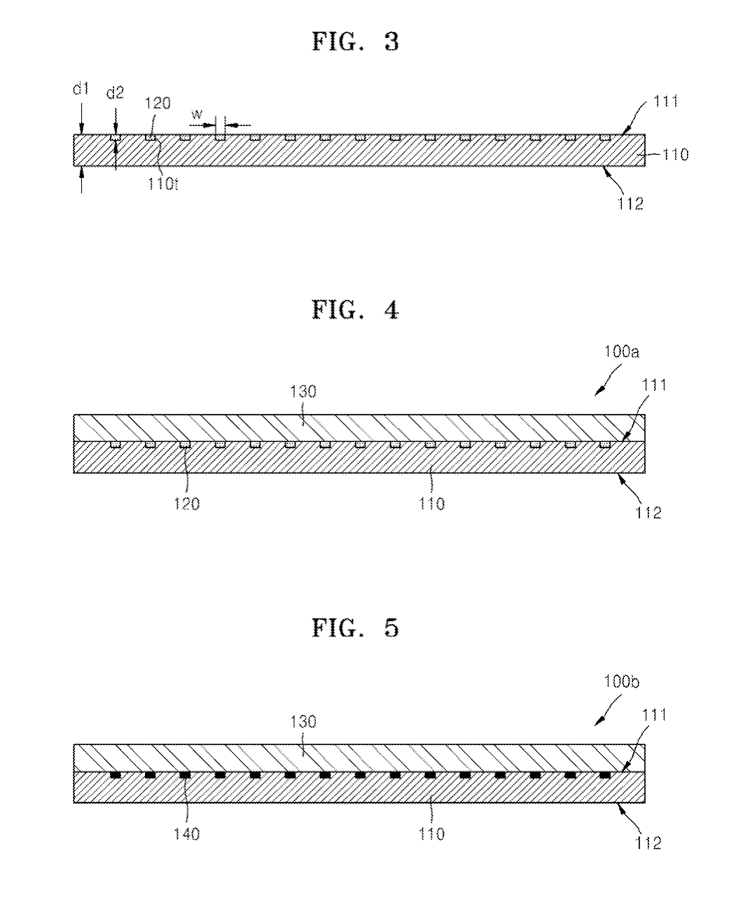

FIG. 1 is a schematic perspective view of a flexible substrate for roll-to-roll processing according to an embodiment of the present invention, FIG. 2 is a schematic plan view of the flexible substrate for roll-to-roll processing of FIG. 1, and FIG. 3 is a schematic cross-sectional view of the flexible substrate for roll-to-roll processing of FIG. 1.

Referring to FIGS. 1 through 3, the flexible substrate 100 for roll-to-roll processing according to an embodiment of the present invention includes a base film 110 and an inorganic mesh pattern 120 formed in the base film 110. The flexible substrate 100 for roll-to-roll processing may have a scroll shape as shown in FIG. 1, and may be rolled or unrolled in a third direction.

The roll-to-roll (R2R) processing that is one of continuous processes creates a new function by coating a specific material or removing a predetermined part by rolling a thin substance, such as a film or a copper foil, around a rotation roller. The roll-to-roll processing is favorable to a mass production, which may advantageously reduce a manufacturing cost.

The flexible substrate 100 for roll-to-roll processing is a flexible substrate that may be used in the roll-to-roll processing, may be rolled in the scroll shape before or after the roll-to-roll processing, may be unrolled in a flat manner during the roll-to-roll processing, and may have a structure in such a manner that the roll-to-roll processing may be endured.

The base film 110 may include an organic polymer material. The base film 110 may include a thermoplastic material. The base film 110 may include at least one selected from the group consisting of polyimide (PI), polyethylene terephthalate (PET), polyethylene naphthalate (PEN), polycarbonate (PC), polyarylate (PAR), polyetherimide (PEI), and polyethersulfone (PES).

The base film 110 may include a material having optical characteristics including a low light transmission, a low optical anisotropy, and a low refractive index. The base film 110 may include a heat resistant material capable of preventing impurities such as oxygen, vapor, and dust from being transmitted and enduring a high processing temperature. The base film 110 may include a material having a low thermal expansion coefficient and a size stability since the base film 110 must be insensitive to a variation of a processing temperature. In addition, the base film 110 may include a material having a small thickness deviation, a high surface smoothness, and an excellent mechanical characteristic such as wear resistance or shock resistance.

The base film 110 may include a first surface 111 and a second surface 112 opposite to the first surface 111 (see FIG. 3). The first surface 111 may be an active surface in which an element is formed. However, the present invention is not limited thereto. The second surface 112 may be the active surface in which the element is formed. The first surface 111 is referred to as a surface in which the inorganic mesh pattern 120 is formed in the present invention.

Trenches 110t may be formed in the first surface 111 of the base film 110 in a mesh shape when seen from the planar point of view. The trenches 110t arranged in the mesh shape may include first trenches 110t1 extending in a first direction and second trenches 110t2 extending in a second direction (see FIG. 2). The first trenches 110t1 and the second trenches 110t2 are used to configure the trenches 110t arranged in the mesh shape and may not be particularly distinguished from each other, except for the extending direction.

The first direction and the second direction may differ from the third direction. Also, the first direction and the second direction may form a right angle. Also, the first direction and the second direction may form an acute angle. For example, the first direction and the second direction may form an angle of 60 degrees.

For example, in a case where a strong tensile force of the third direction is applied to the flexible substrate 100 for roll-to-roll processing, the angle between the first direction and the second direction may be reduced, whereas, in a case where a weak tensile force of the third direction is applied to the flexible substrate 100 for roll-to-roll processing, the first direction and the second direction may form the acute angle closer to the right angle.

A depth d2 of the trenches 110t may be smaller than one-half of a thickness d1 of the base film 110. In a case where the depth d2 of the trenches 110t is smaller than one-half of the thickness d1 of the base film 110, the base film 110 may be modified during a process of forming the trenches 110t. The depth d2 of the trenches 110t may be between 20% and 50% of the thickness d1 of the base film 110. If the depth d2 of the trenches 110t increases, the modification of the base film 100 may be minimized. In particular, in a case where the modification increases due to a difference in a thermal expansion coefficient between the base film 110 and an element formed in an upper portion of the base film 110, the depth d2 of the trenches 110t may increase. That is, the thickness d1 of the base film 110 may be between several tens μm and several hundreds μm. For example, the thickness d1 of the base film 110 may be between 30 μm and 200 μm. In this case, the depth d2 of the trenches 110t may be between 15 μm and 100 μm.

A width w of the trenches 110t may be several tens μm. For example, the width w of the trenches 110t may between 20 μm and 50 μm. That is, the width w of the trenches 110t may be 40 μm The width w of the trenches 110t may be substantially the same as the depth d2 of the trenches 110t. That is, the trenches 110t may have rectangular cross-sections.

Further referring to FIG. 3, the inorganic mesh pattern 120 may bury the trenches 110t of the base film 110. The inorganic mesh pattern 120 may not exist on the first surface 111 of the base film 110. An inorganic material is filled in the trenches 110t of the base film 110, thereby forming the inorganic mesh pattern 120.

According to the present embodiment, the inorganic material of the inorganic mesh pattern 120 may be an inorganic insulation material. That is, the inorganic material may include at least one of oxide, nitride, and oxynitride. For example, the inorganic material may include at least one selected from the group consisting of silicon oxide (SiO₂), silicon nitride (SiNₓ), silicon oxynitride (SiON), aluminium oxynitride (Al₂O₃), titanium oxide (TiO₂), tantalum oxide (Ta₂O₅), hafnium oxynitride (HfO₂), zirconium oxide (ZrO₂), barium strontium titanate (BST), and a lead zirconate-titanate (PZT).

Also, the inorganic material may include a transparent conductive oxide. For example, the inorganic material may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

The inorganic material of the inorganic mesh pattern 120 may be dense, may have a low thermal expansion coefficient, and may have a high size stability compared to the organic material. Also, the inorganic material of the inorganic mesh pattern 120 may have excellent mechanical characteristics such as hardness, wear resistance, and shock resistance compared to the organic material of the base film 110. Thus, the inorganic mesh pattern 120 may perform a function of supplementing the base film 110 formed of the organic material.

In addition, in a case where an element is formed on the base film 110, a problem may exist in that a boundary surface is exfoliated or cracks may occur due to a difference in the thermal expansion coefficient between the base film 110 and the element. However, according to the present invention, the inorganic mesh pattern 120 may be formed on the active surface of the base film 110, a bonding force between the inorganic mesh pattern 120 and an interface of the element is more excellent than a bonding force between the base film 110 formed of the organic material and the element, and thus the problem of exfoliation or crack that may occur in the boundary surface may be resolved. In addition, the inorganic mesh pattern 120 reduces a thermal expansion of the base film 110, thereby reducing a problem that occurs due to the difference in the thermal expansion coefficient between the flexible substrate 100 for roll-to-roll processing and the element.

FIG. 4 is a schematic cross-sectional view of a flexible substrate for roll-to-roll processing according to another embodiment of the present invention.

Referring to FIG. 4, the flexible substrate 100a for roll-to-roll processing is substantially the same as the flexible substrate 100 for roll-to-roll processing of FIGS. 1 through 3 except that the flexible substrate 100a for roll-to-roll processing includes an inorganic insulation layer 130 stacked on the first surface 111 of the base film 110. The differences between the flexible substrate 100a for roll-to-roll processing and the flexible substrate 100 for roll-to-roll processing of FIGS. 1 through 3 will now be described, and descriptions of the same elements therebetween will not be provided here.

Referring to FIG. 4, the flexible substrate 100a for roll-to-roll processing may further include the inorganic insulation layer 130 stacked on the first surface 111 of the base film 110.

The inorganic insulation layer 130 may include at least one selected from the group consisting of silicon oxide (SiO₂), silicon nitride (SiN_{g}), silicon oxynitride (SiON), aluminium oxynitride (Al₂O₃), titanium oxide (TiO₂), tantalum oxide (Ta₂O₅), hafnium oxynitride (HfO₂), zirconium oxide (ZrO₂), barium strontium titanate (BST), and a lead zirconate-titanate (PZT). The inorganic insulation layer 130 may include a plurality of inorganic insulation layers that are stacked on each other. Also, the inorganic insulation layer 130 may further include metal layers disposed between the plurality of inorganic insulation layers. The inorganic insulation layer 130 may further include organic material layers disposed between the inorganic insulation layers.

The inorganic insulation layer 130 may include the same material as the material of the inorganic mesh pattern 120. An element may be formed on the inorganic insulation layer 130 during roll-to-roll processing. According to another example, the element may be formed on the second surface 112 of the base film 110 during roll-to-roll processing.

The inorganic insulation layer 130 may function as a barrier layer that prevents impurities such as oxygen, vapor, and dust from passing therethrough. The inorganic insulation layer 130 may improve a surface characteristic of the base film 110.

FIG. 5 is a schematic cross-sectional view of a flexible substrate for roll-to-roll processing according to another embodiment of the present invention.

Referring to FIG. 5, the flexible substrate 100b for roll-to-roll processing is substantially the same as the flexible substrate 100a for roll-to-roll processing of FIG. 4 except that the flexible substrate 100b for roll-to-roll processing includes a metal mesh pattern 140 instead of the inorganic mesh pattern 120. The differences between the flexible substrate 100b for roll-to-roll processing and the flexible substrate 100a for roll-to-roll processing of FIG. 4 will now be described, and descriptions of the same elements therebetween will not be provided here.

Referring to FIG. 5, the flexible substrate 100b for roll-to-roll processing may include the metal mesh pattern 140.

The metal mesh pattern 140 may bury the trenches 110t of the base film 110. The metal mesh pattern 140 may not exist on the first surface 111 of the base film 110. A metal material is filled in the trenches 110t of the base film 110, thereby forming the metal mesh pattern 140. The metal mesh pattern 140 may have the same shape as the inorganic mesh pattern 120 of FIGS. 1 through 3.

According to the present embodiment, the metal mesh pattern 140 may include metal material. For example, the metal mesh pattern 140 may include a metal such as Ag, Al, Au, Cr, Cu, Mo, Ni, Ti, and Ta. The metal mesh pattern 140 may include an alloy such as Ag, Al, Au, Cr, Cu, Mo, Ni, Ti, and Ta or an alloy such as NiCr, NiV, and SST. The metal mesh pattern 140 has a high mechanical intensity, thereby greatly improving mechanical stability of the flexible substrate 100b for roll-to-roll processing.

The metal mesh pattern 140 may be covered by the inorganic insulation layer 130. An element may be formed on the inorganic insulation layer 130 during roll-to-roll processing.

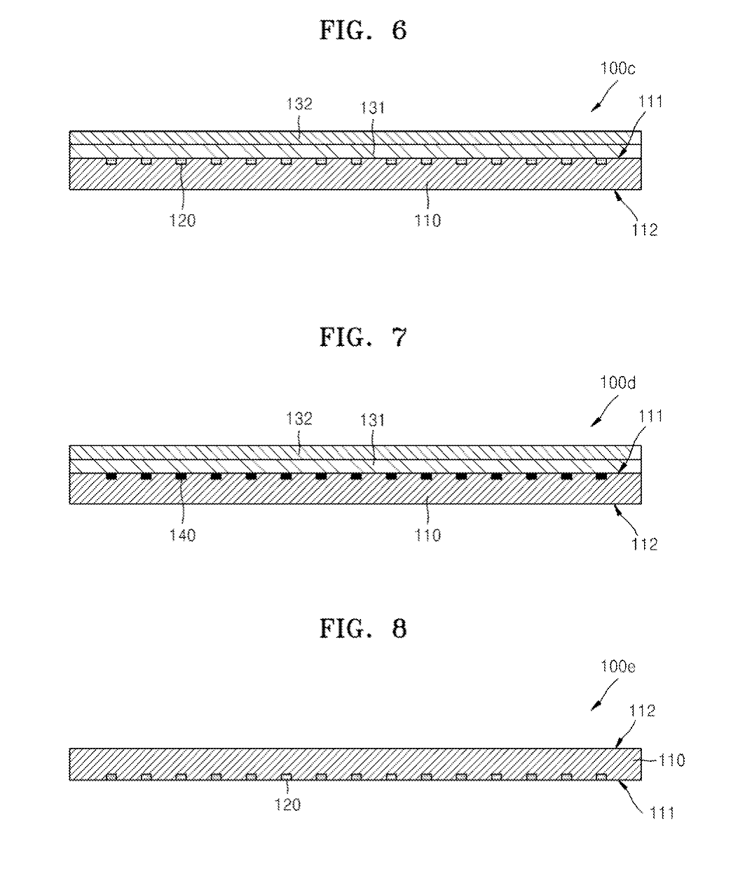

FIG. 6 is a schematic cross-sectional view of a flexible substrate for roll-to-roll processing according to another embodiment of the present invention.

Referring to FIG. 6, the flexible substrate 100c for roll-to-roll processing is substantially the same as the flexible substrate 100a for roll-to-roll processing of FIG. 4 except that the flexible substrate 100c for roll-to-roll processing has a stack structure of a first inorganic insulation layer 131 and a second inorganic insulation layer 132. The differences between the flexible substrate 100c for roll-to-roll processing and the flexible substrate 100a for roll-to-roll processing of FIG. 4 will now be described, and descriptions of the same elements therebetween will not be provided here.

Referring to FIG. 6, the flexible substrate 100c for roll-to-roll processing may include the first inorganic insulation layer 131 and the second inorganic insulation layer 132 that are stacked on the first surface 111 of the base film 110.

The first inorganic insulation layer 131 and/or the second inorganic insulation layer 132 may include at least one selected from the group consisting of silicon oxide (SiO₂), silicon nitride (SiN_{g}), silicon oxynitride (SiON), aluminium oxynitride (Al₂O₃), titanium oxide (TiO₂), tantalum oxide (Ta₂O₅), hafnium oxynitride (HfO₂), zirconium oxide (ZrO₂), barium strontium titanate (BST), and a lead zirconate-titanate (PZT).

Also, although not shown, a metal layer, a transparent conductive oxide layer, or an organic material layer may be disposed between the first inorganic insulation layer 131 and the second inorganic insulation layer 132.

The first inorganic insulation layer 131 may include the same material as that of the inorganic mesh pattern 120. The first inorganic insulation layer 131 and the second inorganic insulation layer 132 may include different materials.

FIG. 7 is a schematic cross-sectional view of a flexible substrate for roll-to-roll processing according to another embodiment of the present invention.

Referring to FIG. 7, the flexible substrate 100d for roll-to-roll processing is substantially the same as the flexible substrate 100b for roll-to-roll processing of FIG. 5 except that the flexible substrate 100d for roll-to-roll processing has a stack structure of the first inorganic insulation layer 131 and the second inorganic insulation layer 132. The differences between the flexible substrate 100d for roll-to-roll processing and the flexible substrate 100b for roll-to-roll processing of FIG. 5 will now be described, and descriptions of the same elements therebetween will not be provided here. Also, the first inorganic insulation layer 131 and the second inorganic insulation layer 132 are described in the embodiment with reference to FIG. 6, and thus detailed descriptions thereof will not be provided.

Referring to FIG. 7, the flexible substrate 100d for roll-to-roll processing may include the metal mesh pattern 140, and may further include the first inorganic insulation layer 131 and the second inorganic insulation layer 132 that cover the metal mesh pattern 140 and the first surface 111 of the base film 110.

FIG. 8 is a schematic cross-sectional view of a flexible substrate for roll-to-roll processing according to another embodiment of the present invention.

Referring to FIG. 8, the flexible substrate 100e for roll-to-roll processing is substantially the same as the flexible substrate 100 for roll-to-roll processing of FIGS. 1 through 3 except that the flexible substrate 100 for roll-to-roll processing of FIGS. 1 through 3 is turned upside down in the present embodiment. The differences between the flexible substrate 100e for roll-to-roll processing and the flexible substrate 100 for roll-to-roll processing of FIGS. 1 through 3 will now be described, and descriptions of the same elements therebetween will not be provided here.

Referring to FIG. 8, the construction of the flexible substrate 100e for roll-to-roll processing is the same as that of the flexible substrate 100 for roll-to-roll processing of FIGS. 1 through 3 turned upside down. That is, the second surface 112 is disposed on an upper portion of the base film 110 and is an active surface in which an element is formed. That is, the inorganic mesh pattern 120 may be formed on a rear surface that is a non-active surface of the base film 110.

The inorganic mesh pattern 120 may be replaced with the metal mesh pattern 140 of FIG. 5.

The inorganic mesh pattern 120 or the metal mesh pattern 140 formed in the non-active surface of the base film 110 may involve an increase in a mechanical intensity of the flexible substrate 100e for roll-to-roll processing and a reduction in the entire thermal expansion coefficient.

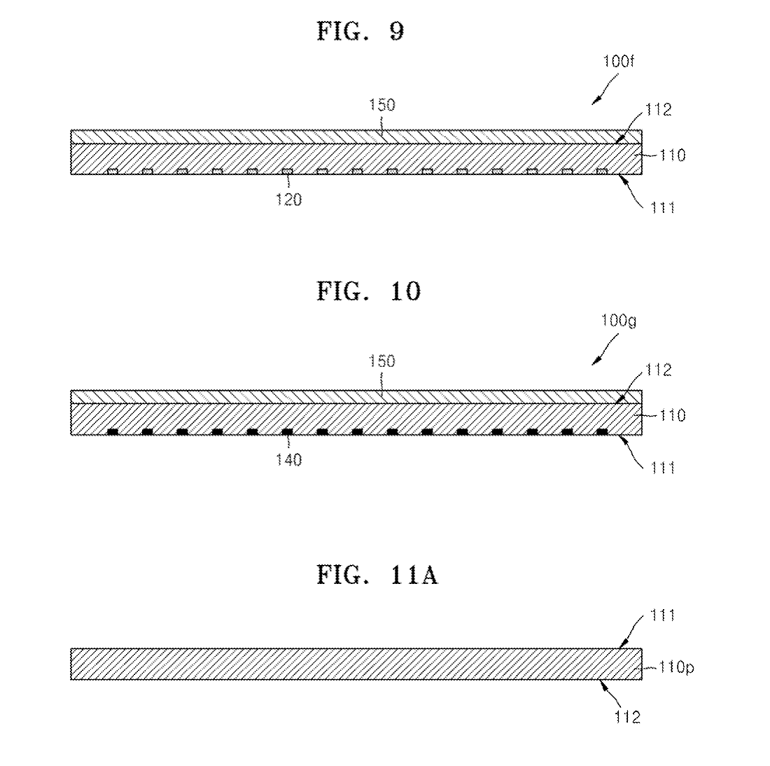

FIG. 9 is a schematic cross-sectional view of a flexible substrate for roll-to-roll processing according to another embodiment of the present invention.

Referring to FIG. 9, the flexible substrate 100f for roll-to-roll processing is substantially the same as the flexible substrate 100e for roll-to-roll processing of FIG. 8 except that the flexible substrate 100f for roll-to-roll processing includes an inorganic insulation layer 150 stacked on the second surface 112 of the base film 110. The differences between the flexible substrate 100f for roll-to-roll processing and the flexible substrate 100e for roll-to-roll processing of FIG. 8 will now be described, and descriptions of the same elements therebetween will not be provided here.

Referring to FIG. 9, the flexible substrate 100f for roll-to-roll processing may include the inorganic insulation layer 150 stacked on the second surface 112 of the base film 110.

The inorganic insulation layer 150 may include at least one selected from the group consisting of silicon oxide (SiO₂), silicon nitride (SiN_{g}), silicon oxynitride (SiON), aluminium oxynitride (Al₂O₃), titanium oxide (TiO₂), tantalum oxide (Ta₂O₅), hafnium oxynitride (HfO₂), zirconium oxide (ZrO₂), barium strontium titanate (BST), and a lead zirconate-titanate (PZT). The inorganic insulation layer 150 may include a plurality of inorganic insulation layers that are stacked on each other. Also, the inorganic insulation layer 150 may further include metal layers disposed between the plurality of inorganic insulation layers. The inorganic insulation layer 150 may further include organic material layers disposed between the inorganic insulation layers.

An element may be formed on the inorganic insulation layer 150 during roll-to-roll processing. The inorganic insulation layer 150 may function as a barrier layer that prevents impurities, such as oxygen, vapor, and dust, from passing therethrough. The inorganic insulation layer 150 may improve a surface characteristic of the base film 110.

FIG. 10 is a schematic cross-sectional view of a flexible substrate for roll-to-roll processing according to another embodiment of the present invention.

Referring to FIG. 10, the flexible substrate 100g for roll-to-roll processing is substantially the same as the flexible substrate 100f for roll-to-roll processing of FIG. 9 except that the flexible substrate 100g for roll-to-roll processing includes the metal mesh pattern 140 instead of the inorganic mesh pattern 120. The differences between the flexible substrate 100g for roll-to-roll processing of FIG. 10 and the flexible substrate 100f for roll-to-roll processing of FIG. 9 will now be described, and descriptions of the same elements therebetween will not be provided here. The metal mesh pattern 140 is described in the embodiment with reference to FIG. 5, and thus a redundant description thereof will not be provided here.

Referring to FIG. 10, the metal mesh pattern 140 is formed on the first surface 111 of the base film 110, and the inorganic insulation layer 150 is formed on the second surface 112 of the base film 110. An active surface of the flexible substrate 100g for roll-to-roll processing may be an upper surface of the inorganic insulation layer 150. That is, an element may be formed on the inorganic insulation layer 150 during roll-to-roll processing.

The second surface 112 of the base film 110 is exposed in FIGS. 3 through 7. However, this is exemplary, and the second surface 112 of the base film 110 may be covered by the inorganic insulation layer 150.

Also, the first surface 111 of the base film 110 may also be covered by the inorganic insulation layer 150.

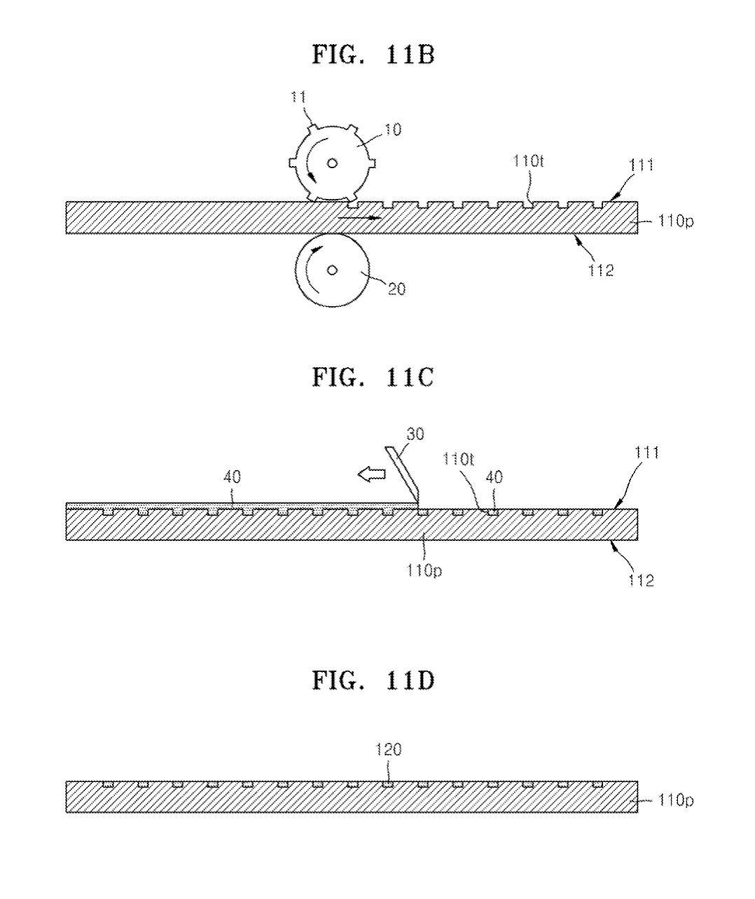

FIGS. 11A through 11D are schematic cross-sectional views for explaining a method of manufacturing a flexible substrate for roll-to-roll processing according to an embodiment of the present invention.

Referring to FIG. 11A, a base film 110p including the first surface 111 and the second surface 112 is prepared. The first surface 111 and the second surface 112 of the base film 110p are flat. A bonding force of the first surface 111 of the base film 110p may be reinforced, and surface processing may be performed using plasma so as to increase flatness.

The base film 110p may include at least one selected from the group consisting of polyimide (PI), polyethylene terephthalate (PET), polyethylene naphthalate (PEN), polycarbonate (PC), polyarylate (PAR), polyetherimide (PEI), and polyethersulfone (PES).

Referring to FIG. 11B, thermal type roll imprinting is performed on the base film 110p and the trenches 110t are formed. The base film 110p may be disposed between a thermal type roll 10 and a support roll 20. The thermal type roll 10 may contact the first surface 111 of the base film 110p. The support roll 20 may contact the second surface 112 of the base film 110p. The thermal type roll 10 may be heated. The thermal type roll 10 and the support roll 20 may be pressurized relative to each other. Protrusions 11 corresponding to the trenches 110t may be formed on a surface of the thermal type roll 10.

The thermal type roll 10 may rotate in a counterclockwise direction. The support roll 20 may rotate in the counterclockwise direction by the thermal type roll 10. According to another example, the support roll 20 may rotate in a clockwise direction so as to have the same line speed as a circumference of the thermal type roll 10. As a result, the base film 110p disposed between the thermal type roll 10 and the support roll 20 may be transferred to the right.

The thermal type roll 10 is in a heating status, and the support roll 20 and the thermal type roll 10 are pressurized relative to each other so that the base film 110p may be modified due to heat and pressure applied thereto. As a result, trenches 110t corresponding to the protrusions 11 of the thermal type roll 10 may be formed in the first surface 111 of the base film 110p. The trenches 110t may include first trenches extending in a first direction and second trenches extending in a second direction and crossing the first trenches.

The thermal type roll 10 and the support roll 20 may continuously form the trenches 110t in the base film 110p. Accordingly, the base film 110p in large quantity may be generated.

Referring to FIG. 11C, a doctor blade 30 may be used to bury an inorganic material 40 in the trenches 110t of the base film 110p. Also, the doctor blade 30 may be used to remove the inorganic material 40 from the first surface 111 of the base film 110p.

In more detail, the inorganic material 40 may be coated on the base film 110p in which the trenches 110t are formed. For example, the inorganic material 40 may be coated on the first surface 111 of the base film 110p by using a slot-die coating method or a bar coating method.

The inorganic material 40 may be a liquefied fluid. The inorganic material 40 may be manufactured using printing ink. The inorganic material 40 may have a solution type in which nano particles and a solvent are mixed. The inorganic material 40 may be filled in the trenches 110t of the base film 110p. The inorganic material 40 may be a metal paste such as an Ag paste. The metal paste may include metals such as Au, Al, and Cu.

When the doctor blade 30 contacts the first surface 111 of the base film 110p, if the base film 110p coated with the inorganic material 40 is moved to the right, the inorganic material 40 coated on the first surface of the base film 110p is removed, and the inorganic material 40 remains only in the trenches 110t of the base film 110p.

The slot-die coating method or the bar coating method may be performed according to roll-to-roll processing. The process of removing the inorganic material 40 coated on the first surface 111 of the base film 110p by using the doctor blade 30 may also be performed according to roll-to-roll processing.

Referring to FIG. 11D, the inorganic material 40 of the trenches 110t is modified to form the inorganic mesh pattern 120. To this end, the liquefied inorganic material 40 may be solidified. More specifically, the base film 110p may be sintered by using a roll in a heating state. That is, the base film 110p may pass through the roll in the heating state for sintering.

The sintering may also be performed by using the roll in the heating state according to roll-to-roll processing.

Therefore, the flexible substrate for roll-to-roll processing of FIG. 11D may be manufactured at small expense in large quantity.

To manufacture the flexible substrate 100a for roll-to-roll processing of FIG. 4, the inorganic insulation layer 130 may be formed on the first surface 111 of the base film 110p.

The inorganic insulation layer 130 may be formed by sputtering. The base film 110p in which the inorganic mesh pattern 120 is transferred, and a target of an inorganic insulation material is sputtered, and thus the inorganic insulation layer 130 may be formed. Such a sputtering deposition process may also be performed according to roll-to-roll processing.

Also, the inorganic insulation layer 130 may be deposited using a chemical vapor deposition method. The chemical vapor deposition method may be performed according to roll-to-roll processing.

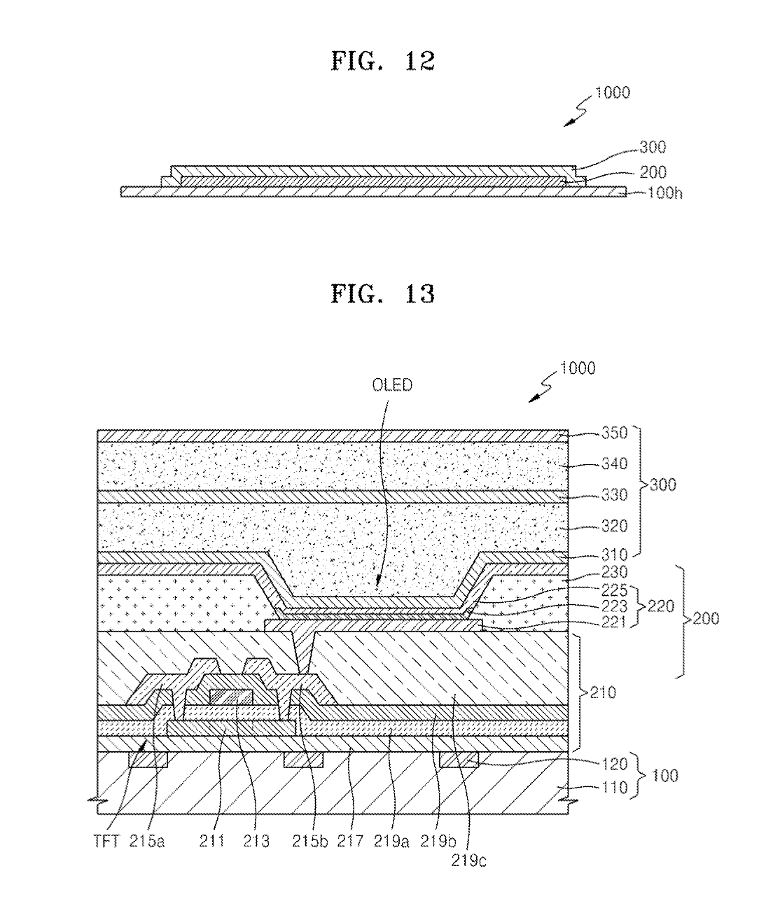

FIG. 12 is a schematic cross-sectional view of an organic light emitting display apparatus including a flexible substrate for roll-to-roll processing according to another embodiment of the present invention, and FIG. 13 is a detailed cross-sectional view of a part of the organic light emitting display apparatus of FIG. 12.

Referring to FIGS. 12 and 13, the organic light emitting display apparatus 1000 includes a flexible substrate 100h, a display unit 200, and an encapsulation thin film 300.

The flexible substrate 100h may be one of the flexible substrates 100 and 100a through 100g described with reference to FIGS. 1 through 11. In FIG. 13, the flexible substrate 100h is exemplarily the flexible substrate 100 of FIGS. 1 through 3.

The flexible substrate 100 may include a base film formed of an organic material and an inorganic mesh pattern formed of an inorganic material. The base film includes a first surface and a second surface opposite the first surface. First trenches extending in a first direction and second trenches extending in a second direction are formed in the first surface.

The display unit 200 includes thin film transistors disposed on the flexible substrate 100h and organic light emitting diodes connected to the thin film transistors.

The encapsulation thin film 300 is formed on the flexible substrate 100h that covers the display unit 200 and has a structure in which a plurality of inorganic films and a plurality of organic films are alternately stacked.

The display unit 200 may be disposed on an upper surface of the flexible substrate 100. A term “display unit 200” mentioned in the present specification is referred to as an organic light emitting diode (OLED) and a thin film transistor (TFT) array for driving the OLED and means a portion indicated by an arrow and a driving portion for displaying an image.

A plurality of pixels are arranged in the display unit 200 in a matrix shape when seen from the plane. Each pixel includes the OLED and an electronic element electrically connected to the OLED. The electronic element may include at least two TFTS, including a driving TFT and a switching TFT, and a storage capacitor. The electronic element operates by being electrically connected to wires and receiving an electrical signal from a driving unit of the outside of the display unit 200. An arrangement of the electronic element electrically connected to the OLED and the wires is referred to as the TFT array.

The display unit 200 includes an element/wire layer 210 including the TFT array, and an OLED layer 220 including an array of OLEDs.

The element/wire layer 210 may include a driving TFT for driving the OLED, a switching TFT (not shown), a capacitor (not shown), and the TFTs or wires (not shown) connected to the capacitor.

A buffer layer 217 may be disposed on the upper surface of the flexible substrate 100 to give flatness and prevent impurities from being diffused. The buffer layer 217 may include silicon oxide, silicon nitride, and/or silicon oxynitride.

An active layer 211 may be disposed in a predetermined region of an upper portion of the buffer layer 217. The active layer 211 may be formed by forming and patterning silicon, an inorganic semiconductor such as an oxide semiconductor or an organic semiconductor in a front surface of the flexible substrate 100 on the buffer layer 217 by using a photolithography process and an etching process. In a case where the active layer 211 is formed of the silicon material, the active layer 211 including a source region, a drain region, and a channel region disposed between the source region and the drain region may be formed by forming and crystallizing an amorphous silicon layer on the front surface of the flexible substrate 100, forming and patterning a polycrystalline silicon layer, and doping impurities on peripheral regions.

A gate insulation film 219a may be disposed on the active layer 211. A gate electrode 213 may be disposed in a predetermined region of an upper portion of the gate insulation film 219a. An interlayer insulation film 219b may be disposed in an upper portion of the gate electrode 213. The interlayer insulation layer 219b may include a contact hole through which the source region and the drain region of the active layer 211 are exposed. A source electrode 215a and a drain electrode 215b may be electrically connected to the source region and the drain region, respectively, of the active layer 211 through the contact hole of the interlayer insulation layer 219b. The TFT may be covered and protected by a passivation film 219c. The passivation film 219c may include an inorganic insulation film and/or an organic insulation film.

The OLED may be disposed in an emission region of an upper portion of the passivation film 219c.

The OLED layer 220 may include a pixel electrode 221 formed on the passivation film 219c, an opposite electrode 225 disposed opposite the pixel electrode 221, and an intermediate layer 223 disposed between the pixel electrode 221 and the opposite electrode 225.

The organic light emitting display apparatus 1000 may be classified as a bottom emission type, a top emission type, or a dual emission type according to the emission direction. The bottom emission type organic light emitting display apparatus includes the pixel electrode 221 as a light transmission electrode and the opposite electrode 225 as a reflection electrode. The top emission type organic light emitting display apparatus includes the pixel electrode 221 as the reflection electrode and the opposite electrode 225 as a semi-transmission electrode. The OLED is described as the top emission type that emits light in a direction of the encapsulation thin film 300 in the present invention.

The pixel electrode 221 may be a reflection electrode. The pixel electrode 221 may have a stack structure of a reflection layer and a transparent electrode layer having a high work function. The reflection layer may include Ag, Mg, Al, Pt, Pd, Au, Ni, Nd, Ir, Cr, Li, and Ca, or an alloy of these. The transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). The pixel electrode 221 may function as an anode electrode.

Meanwhile, a pixel definition film 230 that covers a boundary of the pixel electrode 221 and includes a predetermined opening portion that exposes a center portion of the pixel electrode 221 may be disposed on the pixel electrode 221.

The opposite electrode 225 may be formed as a transmissive electrode. The opposite electrode 225 may be a semi-transmissive film formed of a thin metal material having a low work function such as Li, Ca, LiF/Ca, LiF/Al, Al, Mg, and Ag. To supplement a high resistance problem of the thin metal semi-transmittive film, a transparent conductive film formed of a transparent conductive oxide may be stacked on the metal semi-transmittive film. The opposite electrode 225 may be formed on the front surface of the flexible substrate 100 as a common electrode. The opposite electrode 225 may function as a cathode electrode.

The pixel electrode 221 and the opposite electrode 225 may have opposite polarities.

The intermediate layer 223 may include an emissive layer that emits light. The emissive layer may use a low molecular organic substance or a polymer organic substance. In a case where the emissive layer is a low molecular emissive layer formed of the low molecular organic substance, a hole transport layer (HTL) and a hole injection layer (HIL) may be disposed in a direction of the pixel electrode 221 with respect to the emissive layer, and an electron transport layer (ETL) and an electron injection layer (EIL) may be disposed in a direction of the opposite electrode 225. Function layers in addition to the HIL, the HTL, the ETL, and the EIL may be sacked. Meanwhile, in a case where the emissive layer is a polymeric emissive layer formed of the polymeric organic substance, the HTL may be included in the direction of the pixel electrode 221 with respect to the emissive layer.

Although a structure including the OLED layer 220 disposed on the element/wire layer 210 including the driving TFT is described in the present embodiment, the present invention is not limited thereto. The structure may be modified in various ways such as structures in which the pixel electrode 221 of the OLED is formed on the same layer as the active layer 211 of the TFT, on the same layer as the gate electrode 213 of the TFT, and on the same layer as a source electrode 215a and a drain electrode 215b.

Also, although the gate electrode 213 is disposed on the active layer 211 in the driving TFT in the present embodiment, the present invention is not limited thereto. The gate electrode 213 may be disposed below the active layer 211.

The encapsulation thin film 300 may be disposed on the flexible substrate 100 so as to cover the display unit 200. The OELD included in the display unit 200 is formed of an organic substance and may be easily deteriorated by external moisture or oxygen. Thus, the display unit 200 needs to be encapsulated to protect the display unit 200. The encapsulation thin film 300 may have a structure in which a plurality of inorganic films 310, 330, and 350 and a plurality of organic films 320 and 340 are alternately stacked so as to encapsulate the display unit 200.

The organic light emitting display apparatus 1000 of the present embodiment uses the flexible substrate 110 and the encapsulation thin film 300 as a sealing member, thereby easily implementing a flexible and thin film organic light emitting display apparatus 1000.

The encapsulation thin film 300 may include the plurality of inorganic films 310, 330, and 350 and the plurality of organic films 320 and 340. The plurality of inorganic films 310, 330, and 350 and the plurality of organic films 320 and 340 may be alternately stacked.

The inorganic films 310, 330, and 350 may include metal oxide, metal nitride, and metal carbide or a combination of these. For example, the inorganic films 310, 330, and 350 may include aluminum oxide, silicon oxide, or silicon nitride. According to another example, the inorganic films 310, 330, and 350 may have a stack structure of a plurality of inorganic insulation layers. The inorganic films 310, 330, and 350 may inhibit external moisture and/or oxygen from being diffused into the OLED layer 220.

The organic films 320 and 340 may be a polymeric organic compound. For example, the organic films 320 and 340 may include one of epoxy, acrylate, and urethane acrylate. The organic films 320 and 340 may relax an inner stress of the inorganic films 310, 330, and 350 or supplement defects of the inorganic films 310, 330, and 350 and planarize the inorganic films 310, 330, and 350.

Although the encapsulation thin film 300 includes the three inorganic films 310, 330, and 350 and the two organic films 320 and 340 in FIG. 13, this is exemplary, and a more or less number of inorganic films and organic films may be included in the encapsulation thin film 300.

As described above, according to a flexible substrate for roll-to-roll processing of the present invention, transmission of impurities may be prevented, thermal resistance may be improved, a thermal expansion coefficient may be reduced, a size stability may be improved, and mechanical characteristics such as wear resistance and shock resistance may be improved. That is, thermal, mechanical, and chemical stabilities may be improved. Thus, the flexible substrate for roll-to-roll processing of the present invention may be used to manufacture an organic light emitting display apparatus. Therefore, the organic light emitting display apparatus may be manufactured using roll-to-roll processing, and manufacturing cost thereof may be dramatically reduced.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A flexible substrate for roll-to-roll processing, comprising:
a base film comprising a first surface and a second surface opposite the first surface, the first surface comprising first trenches extending in a first direction and second trenches extending in a second direction, and formed of an organic material; and
an inorganic mesh pattern filled in the first trenches and the second trenches, and formed of an inorganic material.

2. The flexible substrate of claim 1, wherein the first trenches and the second trenches cross each other and are arranged in a mesh shape.

3. The flexible substrate of claim 1, wherein the base film comprises at least one selected from the group consisting of polyimide (PI), polyethylene terephthalate (PET), polyethylene naphthalate (PEN), polycarbonate (PC), polyarylate (PAR), polyetherimide (PEI), and polyethersulfone (PES).

4. The flexible substrate of claim 1, wherein the inorganic mesh pattern comprises an inorganic insulation material.

5. The flexible substrate of claim 1, wherein the inorganic mesh pattern comprises metal.

6. The flexible substrate of claim 1, further comprising an inorganic insulation layer stacked on the first surface of the base film.

7. The flexible substrate of claim 6, wherein the inorganic insulation layer comprises a first inorganic insulation layer and a second inorganic insulation layer stacked on the first inorganic insulation layer.

8. The flexible substrate of claim 1, further comprising an inorganic insulation layer stacked on the second surface of the base film, wherein an element is formed on the inorganic insulation layer.

9. The flexible substrate of claim 1, wherein the flexible substrate has a scroll shape in a third direction that is different from the first direction and second direction.

10. A method of manufacturing a flexible substrate for roll-to-roll processing comprising, the method comprising the steps of:
preparing a base film comprising a first surface and a second surface opposite the first surface, and formed of an organic material;
forming first trenches extending in a first direction and second trenches extending in a second direction in the first surface of the base film; and
forming an inorganic mesh pattern by filling an inorganic material in the first trenches and the second trenches.

11. The method of claim 10, wherein the first trenches and the second trenches are formed by using a thermal type roll imprinting method.

12. The method of claim 10, wherein the inorganic mesh pattern is formed by filling the inorganic material in the first trenches and the second trenches by using a doctor blade, and removing the inorganic material remaining on the first surface of the base film.

13. The method of claim 10, further comprising stacking an inorganic insulation layer on at least one of the first surface and the second surface of the base film.

14. The method of claim 13, wherein the inorganic insulation layer is stacked by using one of a sputtering method and a chemical vapor deposition method.

15. An organic light emitting display apparatus, comprising:
a flexible substrate:
a display unit comprising thin film transistors disposed on the flexible substrate and organic light emitting elements connected to the thin film transistors; and
an encapsulation thin film formed on the flexible substrate to cover the display unit and having a structure in which a plurality of inorganic films and a plurality of organic films are alternately stacked;
wherein the flexible substrate comprises:
a base film comprising a first surface and a second surface opposite the first surface, the first surface comprising first trenches extending in a first direction and second trenches extending in a second direction, and formed of an organic material; and
an inorganic mesh pattern filled in the first trenches and the second trenches, and formed of an inorganic material.
